(19) United States
(12) Patent Application Publication
(10) Pub. No.: US 2026/0221214 A1
(43) Pub. Date: Jul. 30, 2026

(54) Data Storage Device and Method for Read Threshold Calibration in Fractional-Bit-Per-Cell Memory

(71) Applicant: Sandisk Technologies, Inc., Milpitas, CA (US)

(72) Inventors: Eran Sharon, Rishon Lezion (IL); Alexander Bazarsky, Holon (IL)

(73) Assignee: Sandisk Technologies, Inc., Milpitas, CA (US)

(21) Appl. No.: 19/039,962

(22) Filed: Jan. 29, 2025

(51) Int. Cl. G11C 29/52; G11C 16/10; G11C 29/02

(52) U.S. Cl. CPC G11C 29/52; G11C 16/102; G11C 29/022; G11C 2207/2254

(57) ABSTRACT

A data storage device includes a memory that can store a fractional (i.e., non-integer) number of bits per memory cell. For example, a wordline in the memory can have different sets of memory cells, where a stored bit can be inferred from reading a pair of memory cells stored across the different sets. To balance the bit error rate, different program-verify levels can be used in each set. The different program-verify levels can be provided by using different voltage-to-control-gate (VCGR) shifts or by modifying a sense amplifier capacitor integration time. Methods for calibrated read thresholds of entangled pages are also described.

### BACKGROUND

Bits per cell (BPC) refers to the number of bits that can be stored in a non-volatile memory (NVM) cell. Usually, BPC is an integer, such as four bits per cell. While providing a cost savings, using four bits per cell can reduce performance.

### BRIEF DESCRIPTION OF THE DRAWINGS

FIG. 1A is a block diagram of a data storage device of an embodiment.

FIG. 1B is a block diagram illustrating a storage module of an embodiment.

FIG. 1C is a block diagram illustrating a hierarchical storage system of an embodiment.

FIG. 2A is a block diagram illustrating components of the controller of the data storage device illustrated in FIG. 1A according to an embodiment.

FIG. 2B is a block diagram illustrating components of the data storage device illustrated in FIG. 1A according to an embodiment.

FIG. 3 is a block diagram of a host and a data storage device of an embodiment.

FIGS. 4A and 4B are illustrations of independent and entangled memory cells of an embodiment.

FIG. 5 is a flow chart of a method of an embodiment for writing to a memory with an integer number of bits per cell.

FIG. 6 is a flow chart of a method of an embodiment for writing to a memory with a non-integer number of bits per cell.

FIG. 7 is a graph of bit error rate (BER) per page versus average BER of an embodiment that does not use BER balancing.

FIG. 8 is a graph of BER per page versus average BER of an embodiment that uses BER balancing.

FIG. 9 is a graph of charge voltage distribution (CVD) versus DAC of an embodiment that does not use balancing.

FIG. 10 is a graph of CVD versus DAC of an embodiment that uses balancing.

FIG. 11 is a graph of BER versus actual BER of an embodiment.

FIG. 12 is a flow chart of a method of an embodiment for BER balancing in fractional-bits-per-cell memory.

FIG. 13 is a flow chart of a method of an embodiment for extracting read thresholds.

FIG. 14 is a flow chart of a method of an embodiment for performing read threshold calibration.

FIG. 15 is a flow chart of a method of an embodiment for read threshold calibration in fractional-bit-per-cell memory.

### DETAILED DESCRIPTION

The following embodiments generally relate to a data storage device and method for bit-error-rate balancing in fractional-bit-per-cell memory. In one embodiment, a data storage device is provided comprising a memory and one or more processors. The memory comprises a wordline having first and second sets of memory cells. The one or more processors, individually or in combination, are configured to: program memory cells in the first and second sets of memory cells to store a non-integer number of bits in each of the programmed memory cells; and perform bit error rate (BER) balancing by using different program-verify levels in the first and second sets of memory cells.

In another embodiment, a method is provided that is performed in a data storage device comprising a memory comprising a wordline, wherein the wordline comprises first and second sets of memory cells. The method comprises: programming a fractional number of bits per memory cell in memory cells in the first and second sets of memory cells; and using different program-verify levels in the first and second sets of memory cells to balance a bit error rate between the first and second sets of memory cells.

In yet another embodiment, a data storage device is provided comprising: a memory comprising first and second sets of memory cells; and means for bit error rate (BER) balancing by using different program-verify levels to verify programming memory cells in the first and second sets of memory cells when storing a non-integer number of bits in each of the programmed memory cells.

In one embodiment, a data storage device is provided comprising a memory and one or more processors. The memory comprises a wordline, wherein the wordline comprises first and second sets of memory cells. The one or more processors, individually or in combination, are configured to: program a plurality of entangled pages of data in the first and second sets of memory cells, wherein read thresholds are shared between at least some of the plurality of entangled pages; and calibrate read thresholds of one of the plurality of entangled pages.

In another embodiment, a method is provided that is performed in a data storage device comprising a memory, wherein a page of data is stored between first and second sets of fractional bits per cell (BPC) memory cells. The method comprises: fixing some read thresholds of the page of data while scanning other read thresholds of the page of data; performing a bit error rate estimation scan on the page of data to generate optimized scanned read thresholds; fixing the optimized scanned read thresholds and scanning the previously-fixed read thresholds; calibrating the previously-fixed read thresholds; and outputting a set of calibrated read thresholds for the page of data.

In yet another embodiment, a data storage device is provided comprising: a memory comprising first and second sets of memory cells configured to store a plurality of entangled pages; and means for calibrating read thresholds of one of the plurality of entangled pages.

Other embodiments are possible, and each of the embodiments can be used alone or together in combination. Accordingly, various embodiments will now be described with reference to the attached drawings.

### Embodiments

The following embodiments relate to a data storage device (DSD). As used herein, a “data storage device” refers to a non-volatile device that stores data. Examples of DSDs include, but are not limited to, hard disk drives (HDDs), solid state drives (SSDs), tape drives, hybrid drives, etc. Details of example DSDs are provided below.

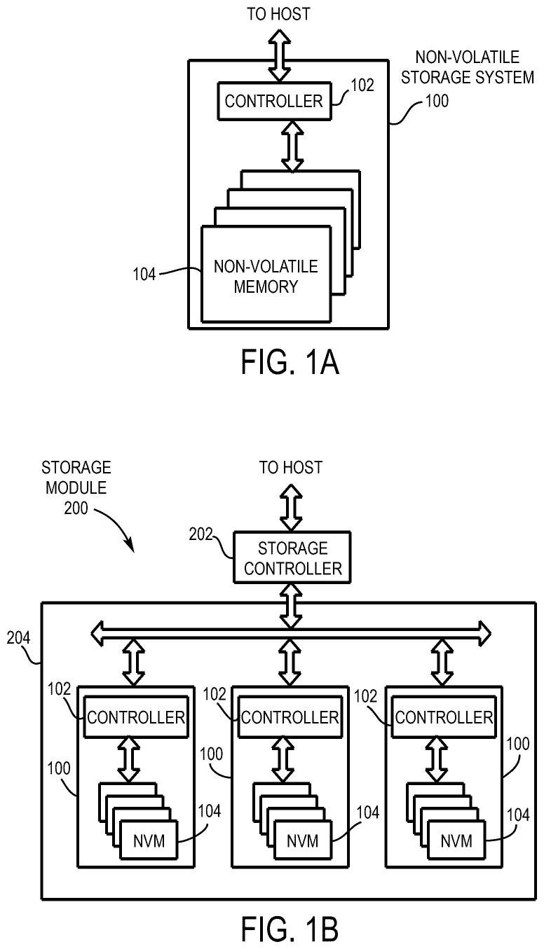

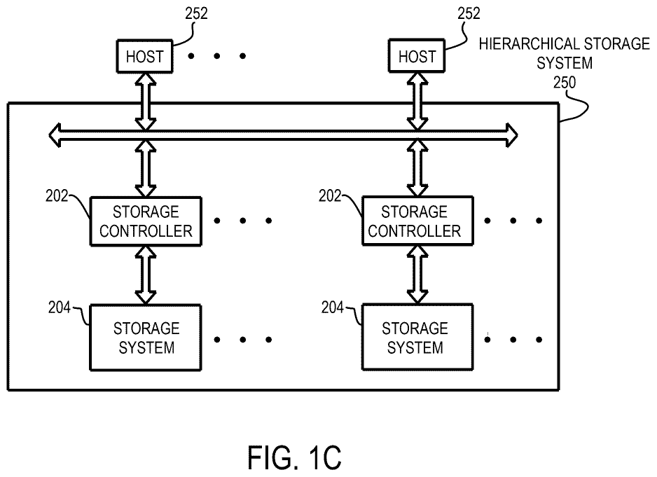

Examples of data storage devices suitable for use in implementing aspects of these embodiments are shown in FIGS. 1A-1C. It should be noted that these are merely examples and that other implementations can be used. FIG. 1A is a block diagram illustrating the data storage device 100 according to an embodiment. Referring to FIG. 1A, the data storage device 100 in this example includes a controller 102 coupled with a non-volatile memory that may be made up of one or more non-volatile memory die 104. As used herein, the term die refers to the collection of non-volatile memory cells, and associated circuitry for managing the physical operation of those non-volatile memory cells, that are formed on a single semiconductor substrate. The controller 102 interfaces with a host system and transmits command sequences for read, program, and erase operations to non-volatile memory die 104. Also, as used herein, the phrase “in communication with” or “coupled with” could mean directly in communication/coupled with or indirectly in communication/coupled with through one or more components, which may or may not be shown or described herein. The communication/coupling can be wired or wireless.

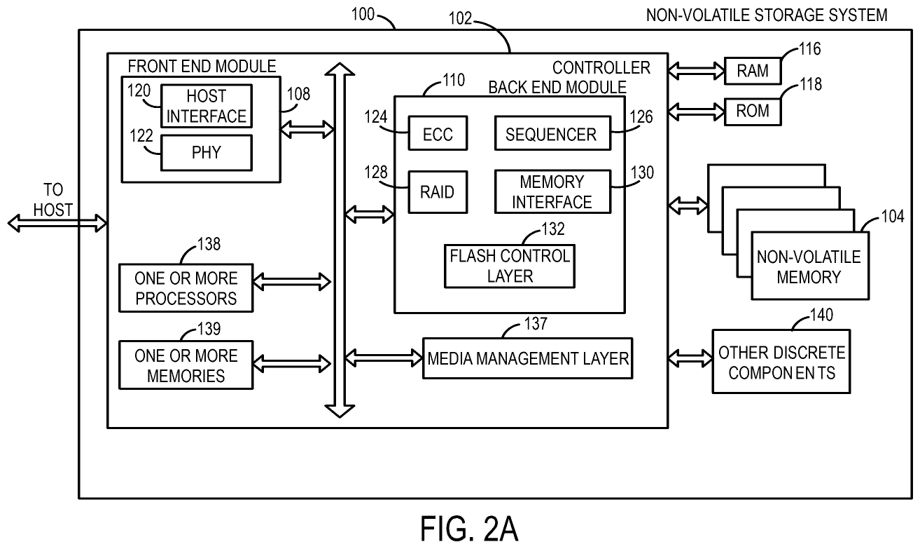

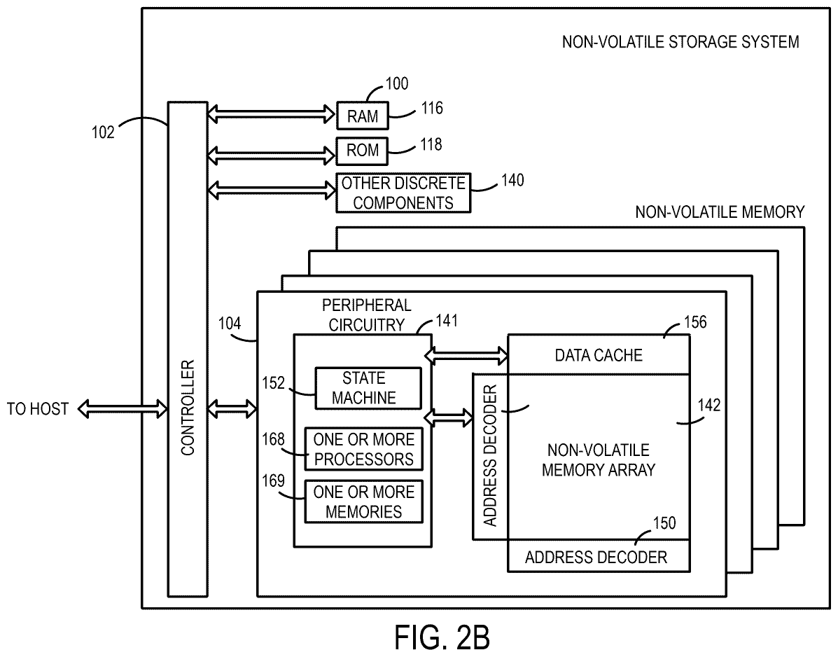

The controller 102 (which may be a non-volatile memory controller (e.g., a flash, resistive random-access memory (ReRAM), phase-change memory (PCM), or magnetoresistive random-access memory (MRAM) controller)) can include one or more components, individually or in combination, configured to perform certain functions, including, but not limited to, the functions described herein and illustrated in the flow charts. For example, as shown in FIG. 2A, the controller 102 can comprise one or more processors 138 that are, individually or in combination, configured to perform functions, such as, but not limited to the functions described herein and illustrated in the flow charts, by executing computer-readable program code stored in one or more non-transitory memories 139 inside the controller 102 and/or outside the controller 102 (e.g., in random access memory (RAM) 116 or read-only memory (ROM) 118). As another example, the one or more components can include circuitry, such as, but not limited to, logic gates, switches, an application specific integrated circuit (ASIC), a programmable logic controller, and an embedded microcontroller.

In one example embodiment, the non-volatile memory controller 102 is a device that manages data stored on non-volatile memory and communicates with a host, such as a computer or electronic device, with any suitable operating system. The non-volatile memory controller 102 can have various functionality in addition to the specific functionality described herein. For example, the non-volatile memory controller can format the non-volatile memory to ensure the memory is operating properly, map out bad non-volatile memory cells, and allocate spare cells to be substituted for future failed cells. Some part of the spare cells can be used to hold firmware (and/or other metadata used for housekeeping and tracking) to operate the non-volatile memory controller and implement other features. In operation, when a host needs to read data from or write data to the non-volatile memory, it can communicate with the non-volatile memory controller. If the host provides a logical address to which data is to be read/written, the non-volatile memory controller can convert the logical address received from the host to a physical address in the non-volatile memory. The non-volatile memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including resistive random-access memory (ReRAM), magnetoresistive random-access memory (MRAM), phase-change memory (PCM), NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC) (e.g., dual-level cells, triple-level cells (TLC), quad-level cells (QLC), etc.) or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, the data storage device 100 may be a card-based system, such as a secure digital (SD) or a micro secure digital (micro-SD) card. In an alternate embodiment, the data storage device 100 may be part of an embedded data storage device.

Although, in the example illustrated in FIG. 1A, the data storage device 100 (sometimes referred to herein as a storage module) includes a single channel between controller 102 and non-volatile memory die 104, the subject matter described herein is not limited to having a single memory channel. For example, in some architectures (such as the ones shown in FIGS. 1B and 1C), two, four, eight or more memory channels may exist between the controller and the memory device, depending on controller capabilities. In any of the embodiments described herein, more than a single channel may exist between the controller and the memory die, even if a single channel is shown in the drawings.

FIG. 1B illustrates a storage module 200 that includes plural non-volatile data storage devices 100. As such, storage module 200 may include a storage controller 202 that interfaces with a host and with data storage device 204, which includes a plurality of data storage devices 100. The interface between storage controller 202 and data storage devices 100 may be a bus interface, such as a serial advanced technology attachment (SATA), peripheral component interconnect express (PCIe) interface, double-data-rate (DDR) interface, or serial attached small scale compute interface (SAS/SCSI). Storage module 200, in one embodiment, may be a solid-state drive (SSD), or non-volatile dual in-line memory module (NVDIMM), such as found in server PC or portable computing devices, such as laptop computers, and tablet computers.

FIG. 1C is a block diagram illustrating a hierarchical storage system. A hierarchical storage system 250 includes a plurality of storage controllers 202, each of which controls a respective data storage device 204. Host systems 252 may access memories within the storage system 250 via a bus interface. In one embodiment, the bus interface may be a Non-Volatile Memory Express (NVMe) or Fibre Channel over Ethernet (FCoE) interface. In one embodiment, the system illustrated in FIG. 1C may be a rack mountable mass storage system that is accessible by multiple host computers, such as would be found in a data center or other location where mass storage is needed.

Referring again to FIG. 2A, the controller 102 in this example also includes a front-end module 108 that interfaces with a host, a back-end module 110 that interfaces with the one or more non-volatile memory die 104, and various other components or modules, such as, but not limited to, a buffer manager/bus controller module that manage buffers in RAM 116 and controls the internal bus arbitration of controller 102. A module can include one or more processors or components, as discussed above. The ROM 118 can store system boot code. Although illustrated in FIG. 2A as located separately from the controller 102, in other embodiments one or both of the RAM 116 and ROM 118 may be located within the controller 102. In yet other embodiments, portions of RAM 116 and ROM 118 may be located both within the controller 102 and outside the controller 102.

Front-end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, serially attached small computer system interface (SAS), Fibre Channel, universal serial bus (USB), PCIe, and NVMe. The host interface 120 typically facilitates transfer for data, control signals, and timing signals.

Back-end module 110 includes an error correction code (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. The controller 102 in this example also comprises a media management layer 137 and a flash control layer 132, which controls the overall operation of back-end module 110.

The data storage device 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller are optional components that are not necessary in the controller 102.

FIG. 2B is a block diagram illustrating components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including ReRAM, MRAM, PCM, NAND flash memory cells and/or NOR flash memory cells in a two-dimensional and/or three-dimensional configuration. Non-volatile memory die 104 further includes a data cache 156 that caches data and address decoders 148, 150. The peripheral circuitry 141 in this example includes a state machine 152 that provides status information to the controller 102. The peripheral circuitry 141 can also comprise one or more components that are, individually or in combination, configured to perform certain functions, including, but not limited to, the functions described herein and illustrated in the flow charts. For example, as shown in FIG. 2B, the memory die 104 can comprise one or more processors 168 that are, individually or in combination, configured to execute computer-readable program code stored in one or more non-transitory memories 169, stored in the memory array 142, or stored outside the memory die 104. As another example, the one or more components can include circuitry, such as, but not limited to, logic gates, switches, an application specific integrated circuit (ASIC), a programmable logic controller, and an embedded microcontroller.

In addition to or instead of the one or more processors 138 (or, more generally, components) in the controller 102 and the one or more processors 168 (or, more generally, components) in the memory die 104, the data storage device 100 can comprise another set of one or more processors (or, more generally, components). In general, wherever they are located and however many there are, one or more processors (or, more generally, components) in the data storage device 100 can be, individually or in combination, configured to perform various functions, including, but not limited to, the functions described herein and illustrated in the flow charts. For example, the one or more processors (or components) can be in the controller 102, memory device 104, and/or other location in the data storage device 100. Also, different functions can be performed using different processors (or components) or combinations of processors (or components). Further, means for performing a function can be implemented with a controller comprising one or more components (e.g., processors or the other components described above).

Returning again to FIG. 2A, the flash control layer 132 (which will be referred to herein as the flash translation layer (FTL) handles flash errors and interfaces with the host. In particular, the FTL, which may be an algorithm in firmware, is responsible for the internals of memory management and translates writes from the host into writes to the memory 104. The FTL may be needed because the memory 104 may have limited endurance, may be written in only multiples of pages, and/or may not be written unless it is erased as a block. The FTL understands these potential limitations of the memory 104, which may not be visible to the host. Accordingly, the FTL attempts to translate the writes from host into writes into the memory 104.

The FTL may include a logical-to-physical address (L2P) map (sometimes referred to herein as a table or data structure) and allotted cache memory. In this way, the FTL translates logical block addresses (“LBAs”) from the host to physical addresses in the memory 104. The FTL can include other features, such as, but not limited to, power-off recovery (so that the data structures of the FTL can be recovered in the event of a sudden power loss) and wear leveling (so that the wear across memory blocks is even to prevent certain blocks from excessive wear, which would result in a greater chance of failure).

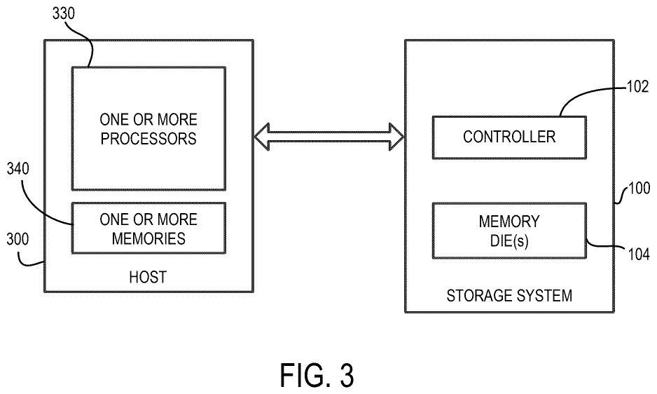

Turning again to the drawings, FIG. 3 is a block diagram of a host 300 and data storage device 100 of an embodiment. The host 300 can take any suitable form, including, but not limited to, a computer, a mobile phone, a tablet, a wearable device, a digital video recorder, a surveillance system, etc. The host 300 in this embodiment (here, a computing device) comprises one or more processors 330 and one or more memories 340. In one embodiment, computer-readable program code stored in the one or more memories 340 configures the one or more processors 330 to perform the acts described herein as being performed by the host 300. So, actions performed by the host 300 are sometimes referred to herein as being performed by an application (computer-readable program code) run on the host 300. For example, the host 300 can be configured to send data (e.g., initially stored in the host's memory 340) to the data storage device 100 for storage in the data storage device's memory 104.

As mentioned above, bits per cell (BPC) refers to the number of bits that can be stored in a non-volatile memory (NVM) cell. Usually, BPC is an integer, such as four bits per cell (“X4”). While providing a cost savings, using four bits per cell (or 16 distinct states per cell) can reduce performance. To provide a tradeoff between performance/reliability and cost saving, a “fractional BPC” memory with a non-integer number of bits per cell (e.g., 3.5 bits per cell (“X3.5”)) can be used. In X3.5 memory, 56 kilobytes (KB) of data are written to 16 KB memory cells in a wordline. In contrast, 48 KB of data are written in three bits per cell (X3) memory, and 64 KB of data are written in four bits per cell (X4) memory. Unlike X3 or X4 memories, the mapping between user data and the various memory cell states is not straightforward in X3.5 memory, and different mappings can be associated with different downsides.

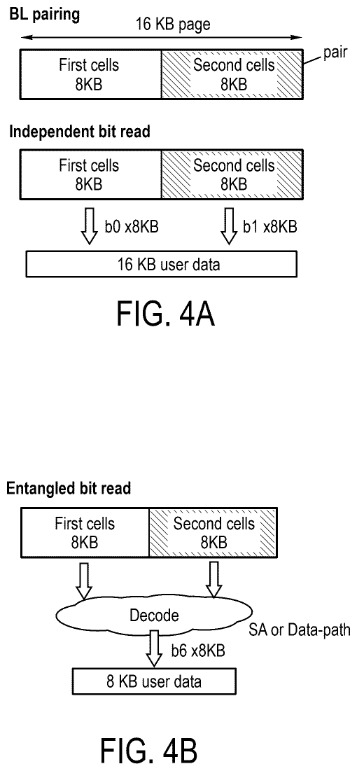

Turning again to the drawings, FIGS. 4A and 4B illustrate a bitline-pairing scheme used to map data and various memory cells states. In this scheme, there is a pair of sets of memory cells within a page. The pair can be independent or entangled, as shown in the examples in FIGS. 4A and 4B, respectively. As shown in these figures, there are two sets of memory cells on the same wordline: a 8 KB set of memory cells on the left-side of the wordline, and an 8 KB set of memory cells on the right-side of the wordline. There are four independent logical pages that include 32 KB (4*8 KB) consisting of only left or right cells and another three entangled logical pages (3*8 KB) that consist of both left and right cells. So, seven bits are stored over two memory cells. Pairs are made within the same page (different column addresses but the same block address). Independent pages have mapping that depends on one cell only, similar to X3 or X4 memory. Entangled pages combine read thresholds from two cells on the same wordline. Entangled bit decoding can be done inside a sense amplifier or in the data path.

Two cells are read to read the page and infer the bit. In order to read an entangled logical page, a logical function is applied on the read results from the two cells. In this example, the first cell is read in state eight (S8), while the second cell is read in state four (S4). Then, a logical operation is applied on both pages, which results in the read bit.

Host data is written directly to a logical page. When reading the data, it can be desirable that different logical pages do not show great difference in throughput and read latency. In order to accomplish this, bit error rate (BER) balancing between the logical pages can be used. Balancing BER can be conducted by moving the states such that they are not uniformly spaced, as is done in X3 and X4 memories. In X3 and X4 memories, all memory cells within a wordline can receive the same read and write/verify threshold shifts, as there was no inherent difference between them. More specifically, a programming procedure of a Flash memory can involve performing multiple programming pulses. After each programming pulse, a set of verify operations is performed to check which cells have reached their target state and can be inhibited. A verify operation is performed by sensing at each verify level corresponding to the target state. Conventionally, the same verify levels are applied to all the cells in the wordline.

However, in X3.5 memory, due to the entangled pages, BER balancing may not be achieved using straightforward verify level optimization as done in X3 and X4 memories. The following embodiments provide new ways to achieve BER balancing in X3.5 memory. These embodiments can improve the BER balancing and reduce the maximum BER with minimal impact on write latency. In general, these embodiments provide several methods to optimize BER balancing in non-volatile memory with entangled pages. These methods can rely on utilizing different aspects of the entangled pages and the memory system.

In one embodiment, a new method for verification is provided for achieving BER balancing of entangled pages in a memory with fractional BPC. While X3.5 memory will be used as an example to illustrate these embodiments, it should be understood that these embodiments can be used with any suitable memory with fractional BPC, and X3.5 should not be read into the claims unless expressly recited therein. In one example implementation, two different verify levels are used for a pair of entangled cells within the same wordline that jointly store a bit. Here, different voltages to control gate (VCGR) shifts are used for the verify levels of each pair of entangled cells. This can involve doubling the number of verify levels, resulting in a slower write speed. For the sake of example, assume that cells 1 and 2 are entangled, cells 3 and 4 are entangled, and so on. Also, assume that the verify level of the odd cells is lower than the verify level of the even cells for all states. According to this procedure, a set of verify operations at increasing verify levels is applied where the odd cells are verified using odd VCGR levels, after which the even cells are verified using the higher even VCGR verify levels. This can be done for all the states in ascending order (e.g., 11 in total for X3.5), using 22 verify levels (i.e., 11 verify levels for the odd cells and 11 different levels for the even cells).

While the system proposed in this embodiment improves balancing, it may incur an increase in write latency due to the increased number of write/verify pulses. As the write thresholds are different, the read thresholds of the entangled cells are also different. This can require calibrating each of the read thresholds separately, having a calibration scheme for the left cell and for the right cell. However, when calibrating entangled pages, there are read thresholds shared between different logical pages.

In another embodiment, modification of the sense amplifier (SA) capacitor integration time may be used instead of modification of VCGR to reduce the write latency, while keeping the double number of verify levels to accommodate for best BER balancing. Modulating capacitor integration time may produce results similar to VCGR modulation without the need to actually modify VCGR, which can incur a higher latency. Using the same VCGR with multiple capacitor integration times can result in faster verification time, leading to a higher programming speed.

This proposed method can be combined with the Quick Pass Write (QPW) approach, in which a memory cell exhibits a high programming pulse (faster programming) until it reaches a first verify level lower than the final verify level of its target state. Once the cell passes the lower verify level, its bit line voltage is adjusted such that following programming pulses will result in smaller threshold voltage (Vt) increments (slower programming) in order to increase the accuracy and tighten the charge voltage distribution (CVD). The QPW scheme can be generalized to use four verify levels per state: slow odd cells, fast odd cells, slow even cells, and fast even cells. These verify levels can be adjusted directly through VCGR or indirectly through SA capacitor integration time modulation.

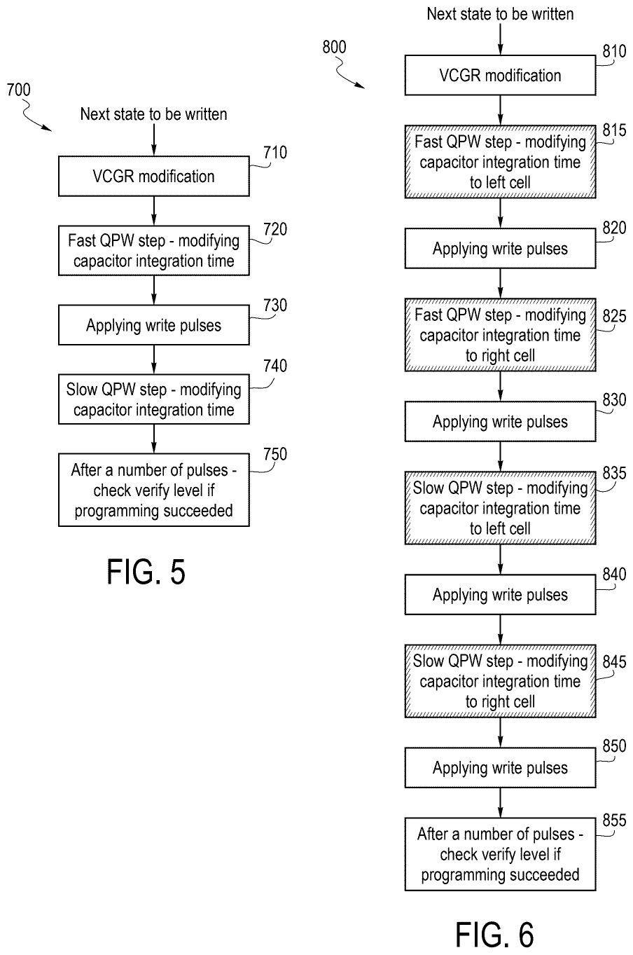

FIGS. 5 and 6 will now be described to contrast a write for a non-fractional BPC (FIG. 5) with a write for a fractional BPC (FIG. 6). As shown in the flow chart 700 in FIG. 5, when a next state is to be written to memory with a non-fractional BPC, the controller 102 of the data storage device 100 modifies VCGR (710) and performs a fast QPW step to modify the capacitor integration time (720). Next, the controller 102 applies write pulses (730) and performs a slow QPW step to modify the capacitor integration time (740). After a number of pulses, the controller 102 checks the verify level to determine if programming succeeded (750).

As shown in the flow chart 800 in FIG. 6, when a next state is to be written to memory with a fractional BPC, the controller 102 of the data storage device 100 modifies VCGR (805) and performs a fast QPW step to modify the capacitor integration time to the left cell (810). Next, the controller 102 applies write pulses (815) and performs a fast QPW step to modify the capacitor integration time to the right cell (820). Then, the controller 102 applies write pulses (825) and performs a slow QPW step to modify the capacitor integration time to the left cell (830). The controller 102 then applies write pulses (835), performs a slow QPW step to modify the capacitor integration time to the right cell (840), and applies additional write pulses (845). After a number of pulses, the controller 102 checks the verify level to determine if programming succeeded (855).

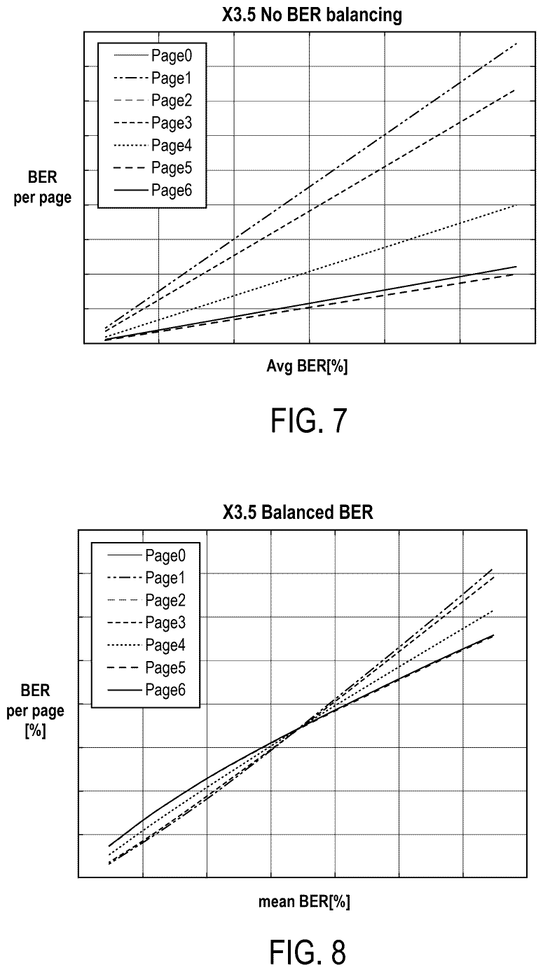

Balancing BER by moving the memory states can incur elevation in the average BER but a reduction in maximum BER. FIGS. 7 and 8 shows the effect of using different BER balancing methods. More specifically, FIG. 7 is a graph of bit error rate (BER) per page versus average BER of an embodiment that does not use BER balancing, and FIG. 8 is a graph of BER per page versus average BER of an embodiment that uses BER balancing. In these graphs, the X axis is the average BER, while the Y axis is the BER per page. In FIG. 7, no balancing is shown. It is clear that each page contributes differently, and the independent pages (non entangled) with more read thresholds (Pages 0-3) contribute more BER. In FIG. 8, balanced BER for a certain average BER point is shown.

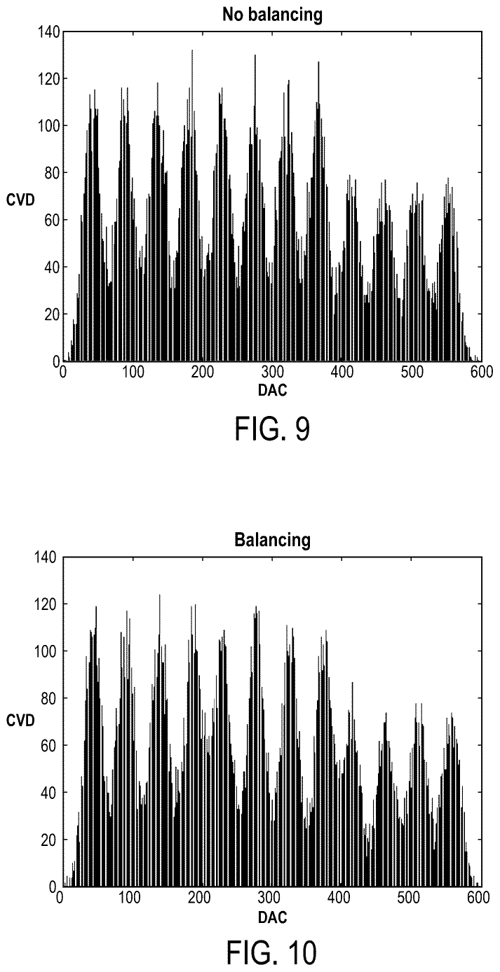

The balancing can also be witnessed when looking on a CVD of an X3.5 wordline. FIG. 9 is a graph of charge voltage distribution (CVD) versus DAC of an embodiment that does not use balancing, and FIG. 10 is a graph of CVD versus DAC of an embodiment that uses balancing. As shown in these graphs, balancing effectively moves the state centers (and read thresholds). Note that the higher voltage states are shorter in both cases due to the X3.5 construction, not the balancing.

These graphs show that balancing can be achieved for a certain average BER point. However, when the BER is lower and (more importantly) higher, the BER is no longer balanced between the pages; but, there are other properties of the entangled pages that may be used to an advantage. Due to the definition of page #5, sensing a soft bit (SB) is less straightforward than the independent pages. In order to acquire an accurate SB, more logical operations can be performed, which can require more time and operational complexity.

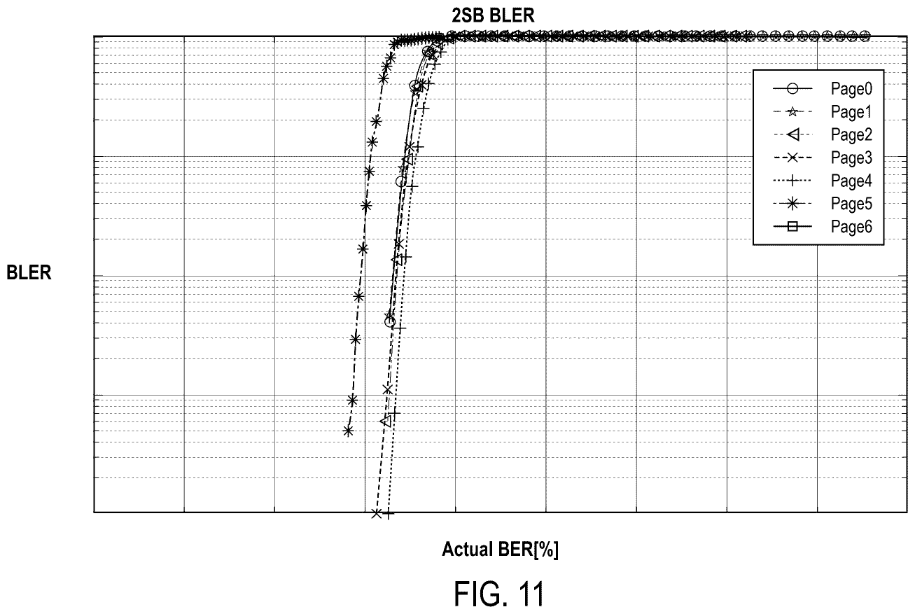

To mitigate this, an inaccurate SB can be sensed for an entangled page. For example, for page 2, if a soft bit read (SBR) by NAND alone is a must, there may be some cells that are flagged with a SB unwantedly. Decoding with the inaccurate SB reduces the correction capability by a certain margin. FIG. 11 shows the correction capability with inaccurate SB for entangled Page5, where the X axis is the actual BER that is measured in the input to the decoder.

When designing this system, the BER balancing can be calibrated such that the page corresponding to the inaccurate SB has a lower chance to meet the higher BER. This BER balancing manipulation can be tailored to the logical mapping so that it makes the most usage of the BER imbalance. In other words, the BER balancing can take into account decoding quality differences between the pages (e.g., Page5 has lower decoding capability due to the suboptimal SB sensing). Specifically, in the example above, the balancing can induce lower BER on Page5 (due to its degraded correction capability) at the expense of slightly higher BER on the other pages.

In another embodiment, when the BER is not fully balanced between the logical pages, data that is more important may be written to the “safer” logical pages. This data can include, for example, a firmware header, important metadata, security keys, computation results, and other objects that are more important than the regular data.

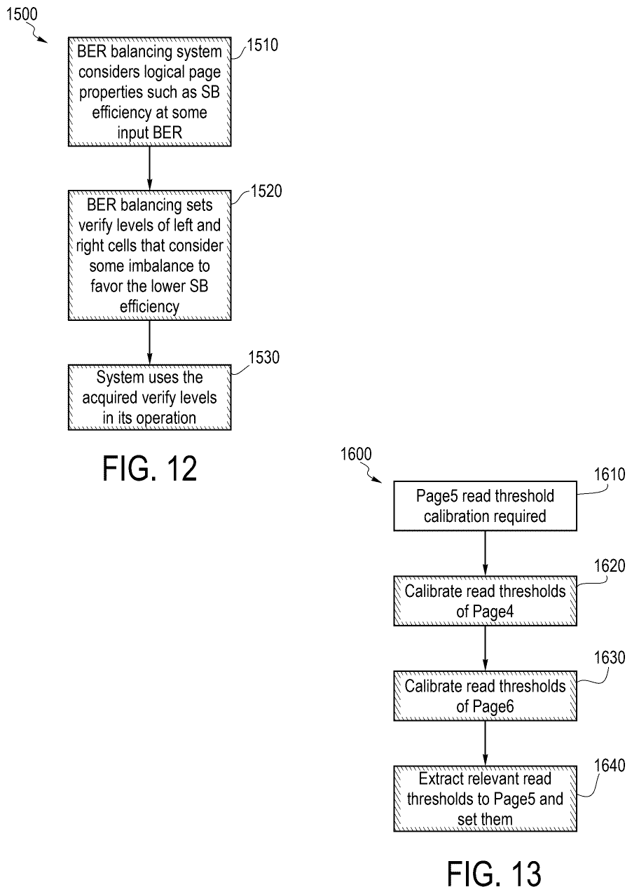

There are several advantages associated with these embodiments. For example, these embodiments can be used to improve BER balancing in X3.5 memory and other “fractional BPC” memories. This avoids reduced performance, correction capability, and increased power consumption, which can occur if there is a failure to balance the BER between pages. In one example implementation, these advantages can be achieved by using the method described in the flow chart 1500 in FIG. 12. As shown in FIG. 12, this method comprises having the BER balancing system (e.g., implemented in the controller 102) consider logical page properties, such as SB efficiency, at some input BER (1510). Next, the BER balancing system sets the verify levels of left and right cells in such a way as to consider some imbalance to favor the lower SB efficiency (1520). The BER balancing system then uses the acquired verify levels in its operation (1530).

Another embodiment relates to read threshold calibration. While independent pages' read thresholds may be calibrated without any modification, there are some challenges with calibrating the read thresholds of certain entangled logical pages, as some pages' read thresholds are shared between different logical pages.

The following embodiments can be used to address read threshold calibration of entangled pages, which can improve the quality of acquired read thresholds, allowing for reduced BER. As a result, throughput may be increased, while power consumption and read latency may be reduced. Also, directly minimizing BER (e.g., by using a BER estimation scan (BES)) can provide advantages over other calibration methods, such as a Valley Search (VS) based method.

In general, these embodiments can be used to calibrate the read thresholds of several entangled pages. Different options to implement the calibration can be used with different tradeoffs between them. The following paragraphs describe options to handle read threshold calibration depending on the entanglement.

### Read Threshold Calibration for Entangled Cells with Identical Read Thresholds

In one embodiment, the read thresholds are equal between the left and right cells. This is the easiest configuration to manage as there is no need to differentiate between the left and right cell read threshold calibration. In this design, when the logical mapping is such that it involves the same thresholds from both the left and right cells, calibration can be performed using a BER Estimation Scan (BES) as if there is only one read threshold. More specifically, a scan can be performed by applying multiple read operations around the single read threshold.

For each such read operation, the entangled bit is produced by applying a logical operation inside the memory 104, and the read page is transferred to the controller 102 for BER estimation. The BER estimation can be done by computing the corresponding syndrome weight of the read page (i.e., by counting the number of unsatisfied parity check equations). This can also be done by using the existing BES engine in a single read threshold mode without the need for hardware changes.

### Read Threshold Calibration for Entangled Cells with Different Read Thresholds

In another embodiment, read thresholds calibrated based on other pages that are shared with the subject entangled page will be used for reading the entangled page.

The flow chart 1600 in FIG. 13 summarizes this aspect. As shown in FIG. 13, in this embodiment, Page5 read threshold calibration is required (1610). The controller 102 calibrates the read thresholds of Page4 (1620) and then calibrates the read thresholds of Page6 (1630). The controller 102 then extracts the relevant read thresholds to Page5 (1640).

### Full Scan

For a full scan approach, in order to calibrate an entangled page that involves N read thresholds, the controller 102 can conduct M\hat{ }N reads, where M is the desired scanning resolution around each of the read thresholds. For each of the M\hat{ }N reads, the controller 102 can calculate the entangled page in the memory die 104 and perform BER estimation on it. The read threshold combination with the minimal syndrome weight can be selected as the optimal. For example, consider Page5, which involves N=2 read thresholds, and assume that a scan resolution of M=7 is required. The controller 102 can conduct 7\hat{ }2 regular read operations (where the entanglement is done in the memory die 104) and perform BER estimation on each of the 49 options. This can be prohibitive due to the large number of sense operations and corresponding latency.

### Emulated Scan

With an emulated scan approach, the memory 104 conducts only M regular read operations (where each operation involves sensing at N read thresholds), and the rest of the processing is performed in the controller 102. As in a regular BES operation, the voltage bin of each cell can be acquired by analyzing the M read pages (i.e., the voltage bin for each cell can be deduced from its M read bits). Once the voltage bin of each cell is determined, the read result of the cell under each of the M\hat{ }N read level combinations can be emulated. From the emulated read result of each of the two entangled cells, the entangled bit is calculated, such that the entangled page is determined. Finally, the BER estimation is performed on the emulated entangled page. The read threshold combination out of the M\hat{ }N combinations corresponding to the minimal BER estimation is determined as the optimal.

In this approach, only M read operations are performed to emulate the M\hat{ }N possible entangled pages, thus resulting in significantly reduced sensing latency (as compared to an actual scan). In some implementations, an emulated scan can require a dedicated ASIC for the X3.5 memory mapping (i.e., dedicated BES logic) in order to perform entangled page calculations.

In entangled pages with several thresholds, it is possible to fix some of the read thresholds while operating BES on the rest of the read thresholds. The read threshold calibration is independent; however, the syndrome weight calculation used in the BES depends on the position of all the read thresholds of the logical page. If the fixed read thresholds are completely off, it would hamper the following BES process conducted in this way. However, if the fixed read thresholds are close enough to the optimal read thresholds, the BES on the rest of the thresholds will find the optimal read thresholds, and then the process can proceed to perform BES on the previously fixed read thresholds.

In one embodiment, one of the thresholds of the entangled pages is fixed, and BES is performed on the other read threshold. Then, the process can be reversed, so that the previously fixed read threshold is also optimized with BES. With this option, the existing ASIC of a conventional memory (with a conventional BES engine) can be used. For example, consider Page5. R3 can be fixed, and a single threshold scan can be performed around R7 and the corresponding single threshold BES. Then, R7 can be fixed according to the BES result, and a single threshold scan can be performed around R3 followed by a single threshold BES operation.

In another embodiment, an indication of BER can be read after the calibration of Page4 to see if Page5 can now be read successfully or whether the calibration of Page6 is required before reading Page5 again. It should be noted that calibration of all read thresholds of a subject page that failed to read is beneficial but does not necessarily need to happen “online” while the host 300 awaits for the requested data. Further, in one embodiment, the data of Page5 may be read after the calibration of Page4, while the calibration of the rest of the read thresholds that depend on Page6 may be completed at a later time during background operations.

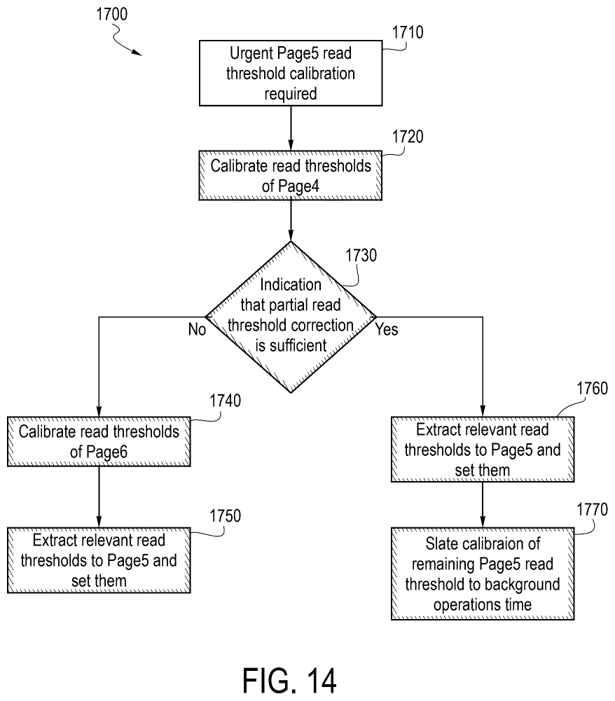

FIG. 14 provides a flow chart 1700 that illustrates these processes. As shown in FIG. 14, an urgent Page5 read threshold calibration is required (1710). After the read thresholds of Page4 are calibrated (1720), the controller 102 determines if there is an indication that partial read threshold correction is sufficient (1730) (e.g., if the partial read threshold calibration calibrates a read threshold that is shared with Page5). If partial read threshold correction is not sufficient, the read thresholds of Page6 (that involve other remaining non calibrated read threshold of Page5) are also calibrated (1740), and the relevant read thresholds to Page5 are extracted (1750). However, if partial read threshold correction is sufficient, the relevant read thresholds to Page5 are extracted without additional calibration (1760), and calibration of remaining Page5 read thresholds are slated to a background operation time (1770). In a general setting, a scheme based on the chosen logical mapping of all the states may need to be set so that the appropriate read threshold calibration scheme can be selected.

As described above, when the same read thresholds are used for both left and right cells, the BER balancing between the pages is suboptimal. As also described above, for the sake of optimal BER balancing, the left and right cells of an entangled page may use different verify levels and hence require different read thresholds when reading the entangled page. In this case, even when the entangled page involves a single threshold, it will effectively involve two read thresholds as threshold of some cells are not identical. Accordingly, if such BER balancing is used, a single threshold entangled page effectively becomes a page with multiple read thresholds, hence the methods described above can be used for this case as well.

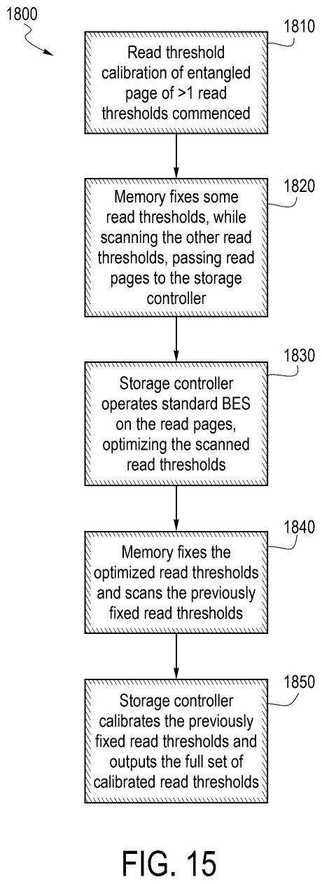

There are several advantages associated with these embodiments. For example, these embodiments can improve aspects of read threshold calibration of X3.5 memory or other fractional bit memories in that well-calibrated read thresholds can improve performance and reduce power consumption. Also, the process of read threshold calibration itself can be restrictively long, and these embodiments can be used to reduce latency. In one example implementation, these advantages can be achieved by using the method described in the flow chart 1800 in FIG. 15. As shown in FIG. 15, after commencement of read threshold calibration of entangled thresholds (1810), the memory 104 fixes some read thresholds (while scanning the other read thresholds) and passes the read pages to the controller 102 (1820). The controller 102 operates standard BES on the read pages, optimizing the scanned read thresholds (1830). The memory 104 fixes the optimized read thresholds and scans the previously fixed read thresholds (1840). Then, the controller 102 calibrates the previously fixed read thresholds and outputs the full set of calibrated read thresholds (1850).

Finally, as mentioned above, any suitable type of memory can be used. Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and wordlines.

A three-dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements in each column. The columns may be arranged in a two-dimensional configuration, e.g., in an x-z plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three-dimensional structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the embodiments described herein can be used alone or in combination with one another.

What is claimed is:

1. A data storage device comprising:
a memory comprising a wordline, wherein the wordline comprises first and second sets of memory cells; and
one or more processors, individually or in combination, configured to:
program a plurality of entangled pages of data in the first and second sets of memory cells, wherein read thresholds are shared between at least some of the plurality of entangled pages; and
calibrate read thresholds of one of the plurality of entangled pages.

2. The data storage device of claim 1, wherein read thresholds for the first and second sets of memory cells are identical, and wherein the read thresholds of the one of the plurality of entangled pages are calibrated using a bit error rate (BER) estimation scan (BES) that applies a plurality of read operations around a single read threshold.

3. The data storage device of claim 1, wherein read thresholds for the first and second sets of memory cells are different, and wherein the read thresholds of the one of the plurality of entangled pages are calibrated based on read thresholds of other ones of the plurality of entangled pages that share a read threshold with the one of the plurality of entangled pages.

4. The data storage device of claim 1, wherein the one or more processors, individually or in combination, are further configured to perform a full scan of the plurality of read thresholds for a desired scanning resolution.

5. The data storage device of claim 1, wherein the one or more processors, individually or in combination, are further configured to perform an emulated scan.

6. The data storage device of claim 1, wherein the one or more processors, individually or in combination, are further configured to calibrate the read thresholds of the one of the plurality of entangled pages by:
performing a partial read threshold calibration on another one of the plurality of entangled pages;
determining whether the partial read threshold calibration provides sufficiently good calibration of a read threshold that is shared with the one of the plurality of entangled pages; and
in response to determining whether the partial read threshold calibration provides sufficiently good calibration of a read threshold that is shared with the one of the plurality of entangled pages, using the calibrated read threshold of the another one of the plurality of entangled pages as a calibrated read threshold of the one of the plurality of entangled pages.

7. The data storage device of claim 6, wherein the one or more processors, individually or in combination, are further configured to:
complete read threshold calibration of the another one of the plurality of entangled pages as a background operation.

8. The data storage device of claim 6, wherein the one or more processors, individually or in combination, are further configured to:
in response to determining that the partial read threshold calibration does not provide sufficiently good calibration of a read threshold that is shared with the one of the plurality of entangled pages:
calibrate a read threshold on yet another one of the plurality of entangled pages; and
use a calibrated read threshold of the yet another one of the plurality of entangled pages as a calibrated read threshold of the one of the plurality of entangled pages.

9. The data storage device of claim 1, wherein the memory comprises a three-dimensional memory.

10. In a data storage device comprising a memory, wherein a page of data is stored between first and second sets of fractional bits per cell (BPC) memory cells:
fixing some read thresholds of the page of data while scanning other read thresholds of the page of data;
performing a bit error rate estimation scan on the page of data to generate optimized scanned read thresholds;
fixing the optimized scanned read thresholds and scanning the previously-fixed read thresholds;
calibrating the previously-fixed read thresholds; and
outputting a set of calibrated read thresholds for the page of data.

11. The method of claim 10, wherein the page of data comprises an entangled page of data.

12. The method of claim 10, further comprising performing a full scan of the read thresholds of the page of data at a desired scanning resolution.

13. The method of claim 10, further comprising performing an emulated scan of the read thresholds of the page of data.

14. The method of claim 10, further comprising:
performing a partial read threshold calibration on another page of data;
determining whether the partial read threshold calibration provides sufficiently good calibration of a read threshold that is shared with the page of data; and
in response to determining whether the partial read threshold calibration calibrates a read threshold that is shared with the page of data, using the calibrated read threshold of the another page of data as a calibrated read threshold of the page of data.

15. The method of claim 14, further comprising:
completing read threshold calibration of the another page of data as a background operation.

16. The method of claim 14, further comprising:
in response to determining that the partial read threshold calibration does not provide sufficiently good calibration of a read threshold that is shared with the page of data:
calibrating a read threshold on yet another page of data; and
using a calibrated read threshold of the yet another page of data as a calibrated read threshold of the page of data.

17. The method of claim 10, wherein the scanning is performed by the memory.

18. The method of claim 10, wherein the bit error rate estimation scan is performed by a controller in the data storage device.

19. The method of claim 10, further comprising using the set of calibrated read thresholds to read the page of data.

20. A data storage device comprising:
a memory comprising first and second sets of memory cells configured to store a plurality of entangled pages; and
means for calibrating read thresholds of one of the plurality of entangled pages.
